(19) United States
(12) Patent Application Publication
(10) Pub. No.: US 2026/0333640 A1
(43) Pub. Date: Oct. 22, 2026

(54) HEAT DISSIPATION MODULE

(71) Applicant: AURAS TECHNOLOGY CO., LTD., New Taipei City (TW)

(72) Inventors: Wan-Fang Lin, New Taipei City (TW); Ni-Ni Lee, New Taipei City (TW); Chien-Chih Su, New Taipei City (TW)

(21) Appl. No.: 19/408,442

(22) Filed: Dec. 4, 2025

(30) Foreign Application Priority Data
Apr. 18, 2025 (TW) 114114803

(51) Int. Cl. H05K 7/20; H05K 1/02

(52) U.S. Cl. CPC H05K 7/20409; H05K 1/0203

(57) ABSTRACT

Disclosed is a heat dissipation module, which includes a thermally conductive member movably and floatingly disposed on a circuit board and including a protruding ring portion and a through hole passing through the protruding ring portion, a locking member penetrating through the through hole and fixedly connected to the circuit board, and at least one elastic member connected to the thermally conductive member and abutting against the circuit board, wherein the protruding ring portion is movable close to or away from the circuit board along the locking member to compress or release the elastic member.

### CROSS-REFERENCE TO RELATED APPLICATION

This application claims the benefit of Taiwan Patent Application Serial No. 114114803 filed on Apr. 18, 2025. The entirety of each Application is incorporated herein by reference.

### BACKGROUND

### 1. Technical Field

The present disclosure relates to a heat dissipation module, and more particularly, to a heat dissipation module adaptable to solid state drive cards of various thicknesses.

### 2. Description of Related Art

With modernization, computers and various electronic devices have rapidly developed and continuously improved in performance. However, heat dissipation issues brought about by high performance hardware also arise. Generally, computers and various electronic devices typically employ heat dissipation elements to dissipate heat. For example, thermal grease or heat sinks can be attached onto an electronic element to be dissipated in order to absorb and disperse heat generated by the electronic element.

Heat dissipation is also required by a solid state drive card disposed on a mother board. However, the conventional heat dissipation device for a solid state drive card is commonly fixed at a uniform height to interpose the solid state drive card between the mother board and the heat dissipation device. Nevertheless, the thickness of a solid state drive card varies depending on the height of a chip used. This leads to a larger interference amount and greater compressive strength applied by a current heat dissipation device to a solid state drive card with a thicker thickness, possibly crushing the chip.

### SUMMARY

A heat dissipation module for a circuit board having a connector connected to a storage component, which comprises: a thermally conductive member movably and floatingly disposed above the circuit board and including a first surface, a second surface opposing to the first surface, a protruding ring portion, a through hole, and an accommodation space, wherein the first surface faces the circuit board, the protruding ring portion extends outward from the first surface, surrounds and defines the accommodation space, such that the accommodation space is exposed at the second surface, and the through hole passes through the protruding ring portion and communicates with the accommodation space; a locking member penetrating through the through hole, fixedly connected to the circuit board and including a head portion, wherein the head portion is accommodated in the accommodation space and is spaced apart from the circuit board; and at least one elastic member connected to the first surface of the thermally conductive member, abutting against the circuit board, and configured to constantly provide an elastic force; wherein the protruding ring portion of the thermally conductive member is configured to move close to or away from the circuit board along the locking member to compress or release the elastic member, and the elastic force is configured to maintain the thermally conductive member in contact with the storage component.

In the aforementioned heat dissipation module, the elastic member comprises a fixing portion and two wing portions, the fixing portion is fixedly connected to the first surface of the thermally conductive member, the two wing portions respectively extend outward from opposite sides of the fixing portion and abut against the circuit board, and the elastic member is configured to provide the elastic force by varying angles between the two wing portions and the fixing portion.

In the aforementioned heat dissipation module, the fixing portion includes two protruding posts, the thermally conductive member further includes at least two penetrating holes, and the two protruding posts respectively penetrate through the two penetrating holes.

In the aforementioned heat dissipation module, each of the two protruding posts is configured to be heat-melted to include a head section and a stem section, the head section and the stem section jointly form a T-shaped cross section, the stem sections of the two protruding posts penetrate through the two penetrating holes, and the head sections of the two protruding posts abut against the second surface of the thermally conductive member.

In the aforementioned heat dissipation module, each of the two wing portions includes a support post, and the support posts abut against the circuit board and respectively correspond to opposite long edges of the thermally conductive member.

In the aforementioned heat dissipation module, the locking member includes a stepped portion and a threaded portion, the stepped portion extends outward from the head portion and penetrates through the through hole, and the threaded portion extends outward from the stepped portion and is fixedly threaded to the circuit board.

In the aforementioned heat dissipation module, a cross-sectional area of the head portion is larger than a cross-sectional area of the through hole, and the cross-sectional area of the through hole is larger than a cross-sectional area of the stepped portion.

In the aforementioned heat dissipation module, the protruding ring portion includes a ring wall and a base plate connected to an end of the ring wall, the through hole passes through the base plate, a thickness of the base plate is less than a height of the stepped portion, and the base plate is configured to move along the stepped portion and is limited between the head portion and the circuit board.

The aforementioned heat dissipation module further comprises a first thermally conductive adhesive pad disposed on the second surface of the thermally conductive member and being in contact with the storage component disposed over the second surface of the thermally conductive member.

The aforementioned heat dissipation module further comprises a heat dissipation sheet disposed on the storage component, and a second thermally conductive adhesive pad disposed between the heat dissipation sheet and the storage component.

In the aforementioned heat dissipation module, the circuit board includes a fixed screw, the fixed screw and the connector are respectively correspondingly adjacent to opposite short edges of the thermally conductive member, a plurality of fastening members penetrate through the heat dissipation sheet and are respectively screw-fastened to the connector and the fixed screw, and the heat dissipation sheet is in contact with the second thermally conductive adhesive pad.

To sum up, the elastic member according to the present disclosure can effectively match to the thickness variations of each of components within the heat dissipation module, or the thickness or height variations of each of electronic components connected to the heat dissipation module, by undergoing compression or release. The elastic member automatically adjusts interference amount applied to the storage component, thereby avoiding the storage component from being damaged due to over compressive strength, while simultaneously maintaining heat transfer efficiency.

### BRIEF DESCRIPTION OF THE DRAWINGS

FIG. 1 is a schematic exploded view of a heat dissipation module according to the present disclosure.

FIG. 2 is a schematic exploded view of a heat dissipation module from another perspective according to the present disclosure.

FIG. 3 is a schematic overall view of a heat dissipation module during use according to the present disclosure.

FIG. 4 is a schematic exploded view of FIG. 3.

FIG. 5 is a schematic cross-sectional view taken along a line A-A in FIG. 3.

FIG. 6 is a schematic cross-sectional view taken along a line B-B in FIG. 3.

FIG. 7 is a schematic cross-sectional view of a heat dissipation module according to another embodiment in the present disclosure.

FIGS. 8, and 9 are respectively schematic cross-sectional views of other embodiments in FIGS. 5, and 6.

### DETAILED DESCRIPTION OF THE EMBODIMENTS

Embodiments of the present disclosure are illustrated with implementations. Other advantages and technical effects of the present disclosure can be readily understood by one with ordinary skills in the art upon reading the disclosure provided herein, and can be used or applied in other different implementations.

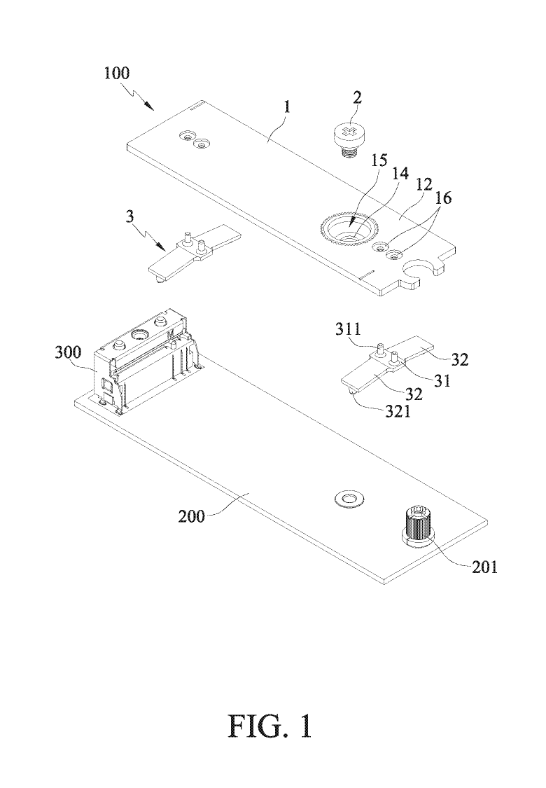

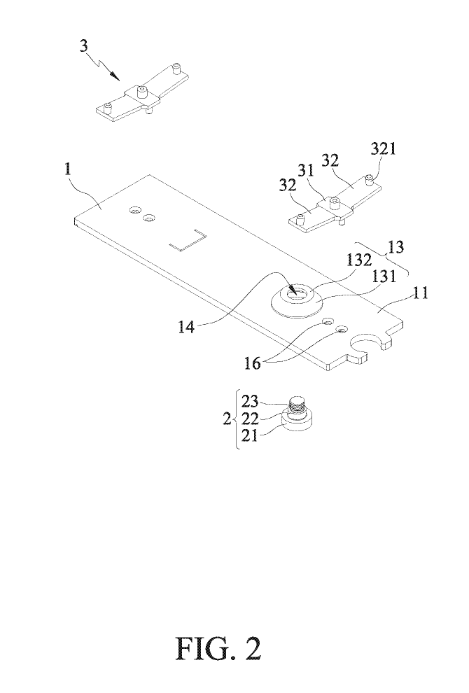

Please refer to FIGS. 1, and 2 a heat dissipation module 100 according to the present disclosure can be disposed on a circuit board 200 (e.g., a mother board). The circuit board 200 includes a connector 300. The heat dissipation module 100 includes a thermally conductive member 1, a locking member 2, and two elastic members 3.

The thermally conductive member 1 is generally in the form of a rectangular plate, and includes a first surface 11, a second surface 12 opposing the first surface 11, a protruding ring portion 13, a through hole 14, an accommodation space 15, and a plurality of penetrating holes 16. The thermally conductive member 1 is disposed above the circuit board 200 with the first surface 11 thereof facing the circuit board 200. The protruding ring portion 13 extends outward from the first surface 11 of the thermally conductive member 1 (i.e., the protruding ring portion 13 extends toward the circuit board 200) and includes a ring wall 131 and a base plate 132. The ring wall 131 has a generally circular cross section and tapers away from the first surface 11. The base plate 132 is connected to the end of the ring wall 131, the base plate 132 and the ring wall 131 jointly surround and define the accommodation space 15, such that the accommodation space 15 is exposed at the second surface 12. The through hole 14 passes through the base plate 132 and communicates with the accommodation space 15. The penetrating holes 16 are in sets of two and are respectively formed at opposite sides of the thermally conductive member 1.

In an embodiment, the thermally conductive member 1 may be made of metal with thermal conductivity (e.g., aluminum or copper), but the present disclosure is not limited thereto.

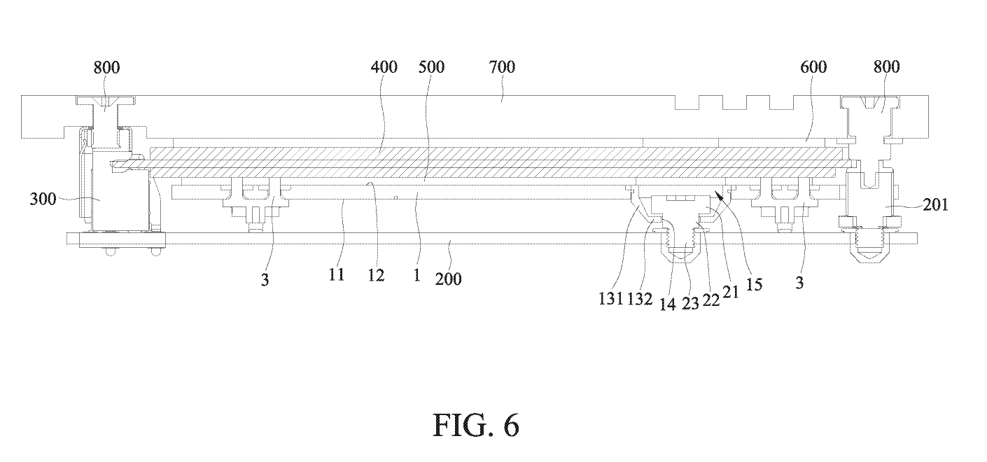

Please also refer to FIG. 6, the locking member 2 penetrates through the through hole 14 and is fixedly connected to the circuit board 200. The locking member 2 includes a head portion 21, a stepped portion 22, and a threaded portion 23. The head portion 21 is accommodated in the accommodation space 15 and is spaced apart from the circuit board 200. The stepped portion 22 extends outward from the head portion 21 and penetrates through the through hole 14. The threaded portion 23 extends outward from the stepped portion 22 and is fixedly threaded to the circuit board 200.

In an embodiment, the cross-sectional area of the head portion 21 is larger than the cross-sectional area of the through hole 14, so that the head portion 21 cannot penetrate the through hole 14 and can only be accommodated in the accommodation space 15. The cross-sectional area of the through hole 14 is larger than the cross-sectional area of the stepped portion 22, and the thickness of the base plate 132 is less than the height of the stepped portion 22 extending vertically from the circuit board 200. Consequently, the base plate 132 can move along the annular side surface of the stepped portion 22 via the through hole 14 and is limited between the head portion 21 and the circuit board 200. In other words, the thermally conductive member 1 is movably and floatingly disposed above the circuit board 200 via the locking member 2.

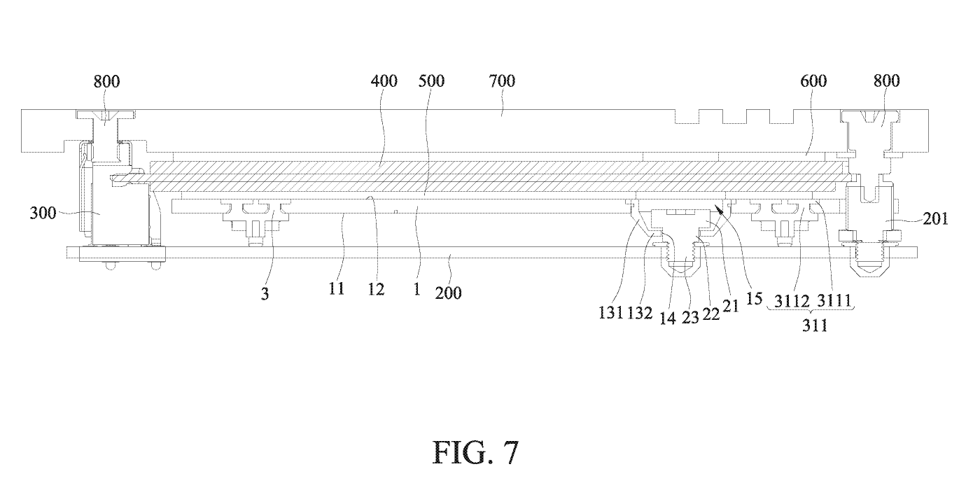

The elastic member 3 includes a fixing portion 31 and two wing portions 32. The fixing portion 31 is generally in the form of a rectangular plate and includes two protruding posts 311. The protruding posts 311 respectively penetrate through the penetrating holes 16. In an embodiment, the fixing portion 31 can be fixedly disposed on the first surface 11 of the thermally conductive member 1, for example, by snapping or adhering the protruding posts 311 in the penetrating holes 16, but ways to fixedly dispose are not limited to the above. In an embodiment, as shown in FIG. 7, after the protruding posts 311 respectively penetrate through the penetrating holes 16, the protruding posts 311 are melted in a heat-melting manner, so that each of the protruding posts 311 includes a head section 3111 and a stem section 3112. The cross-sectional area of the head section 3111 is larger than the cross-sectional area of the stem section 3112, such that the head section 3111 and the stem section 3112 jointly form a T-shaped cross section. The stem section 3112 penetrates through the penetrating hole 16, the head section 3111 abuts against the second surface 12 of the thermally conductive member 1, thereby securing the fixing portion 31 to the first surface 11 of the thermally conductive member 1.

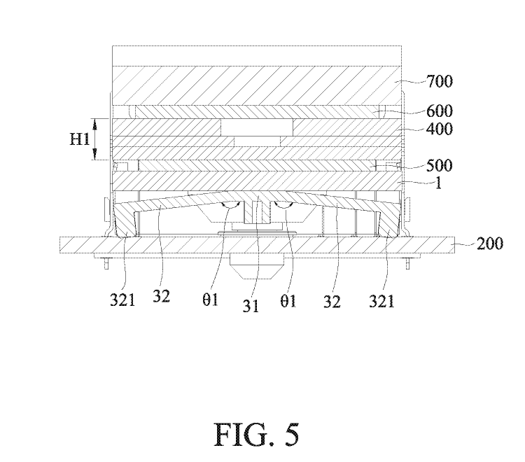

Please also refer to FIG. 5, the wing portions 32 are generally in the form of a rectangular plate and respectively extend outward from opposite sides of the fixing portion 31, and an angle θ1 is formed between the wing portion 32 and the fixing portion 31. Each wing portion 32 further includes a support post 321, which extends in a direction opposite to that of the protruding post 311. The support posts 321 respectively correspond to opposite long edges of the thermally conductive member 1 to abut against the circuit board 200.

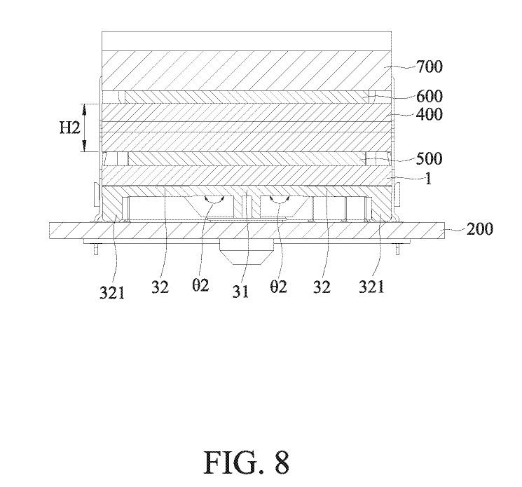

In an embodiment, the elastic member 3 can be made of metal, plastic, or stainless steel with elasticity, and provides an elastic force by varying the angle θ1 between the wing portion 32 and the fixing portion 31. For example, as the protruding ring portion 13 moves along the locking member 2 and is close to the circuit board 200, the angle θ1 between the wing portion 32 and the fixing portion 31 increases, causing the elastic member 3 to be compressed and thereby becoming bigger, longer, or wider (as shown in FIG. 8). By contrast, as the protruding ring portion 13 moves along the locking member 2 and is away from the circuit board 200, the angle θ1 between the wing portion 32 and the fixing portion 31 decreases, allowing the elastic member 3 to be released and thereby becoming smaller, shorter, or narrower (as shown in FIG. 5).

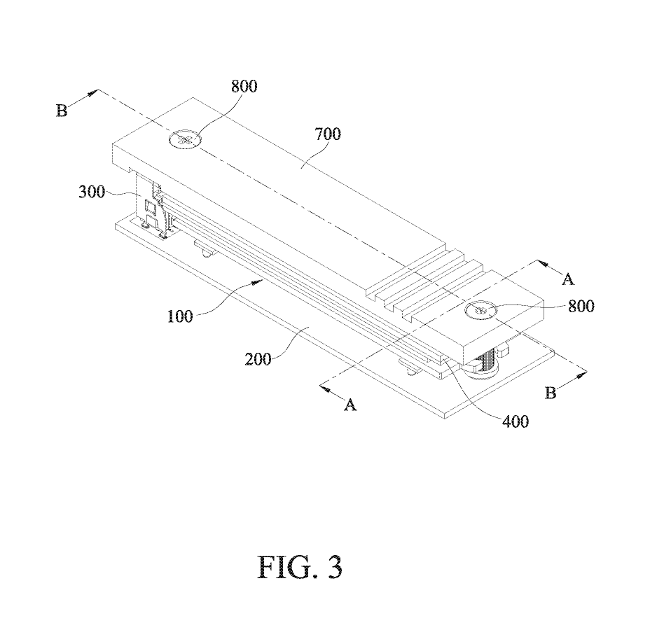

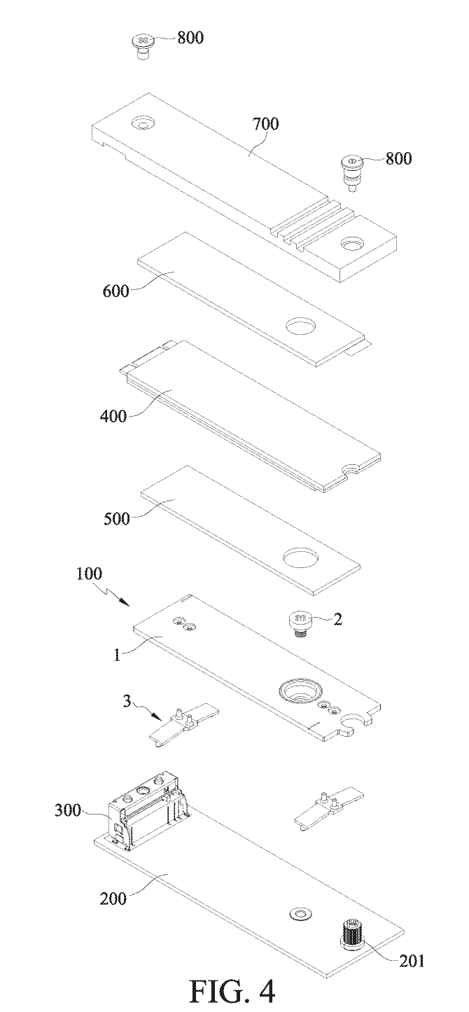

Please refer to FIGS. 3, and 4, a first thermally conductive adhesive pad 500 with thermal conductivity can be disposed on the second surface 12 of the thermally conductive member 1. A storage component 400 is connected to a connector 300, is disposed on the second surface 12 of the thermally conductive member 1, and is in contact with the first thermally conductive adhesive pad 500, such that heat generated by an electronic component (e.g., a chip) disposed on the storage component 400 can be dissipated via the first thermally conductive adhesive pad 500 and the thermally conductive member 1.

A second thermally conductive adhesive pad 600 with thermal conductivity can also be disposed on the storage component 400. A heat dissipation sheet 700 is disposed on the storage component 400, and the second thermally conductive adhesive pad 600 is interposed between the heat dissipation sheet 700 and the storage component 400.

In an embodiment, the circuit board 200 includes a fixing screw 201 spaced apart from the connector 300, and the fixing screw 201 and the connector 300 are respectively correspondingly adjacent to opposite short edges of the thermally conductive member 1. A plurality of fastening members 800 penetrate through opposite ends of the heat dissipation sheet 700 and are respectively screw-fastened to the connector 300 and the fixing screw 201, so that the heat dissipation sheet 700 can be in contact with the second thermally conductive adhesive pad 600. Thus, heat generated by an electronic component (e.g., a chip) disposed on the storage component 400 can be dissipated via the second thermally conductive adhesive pad 600 and the heat dissipation sheet 700.

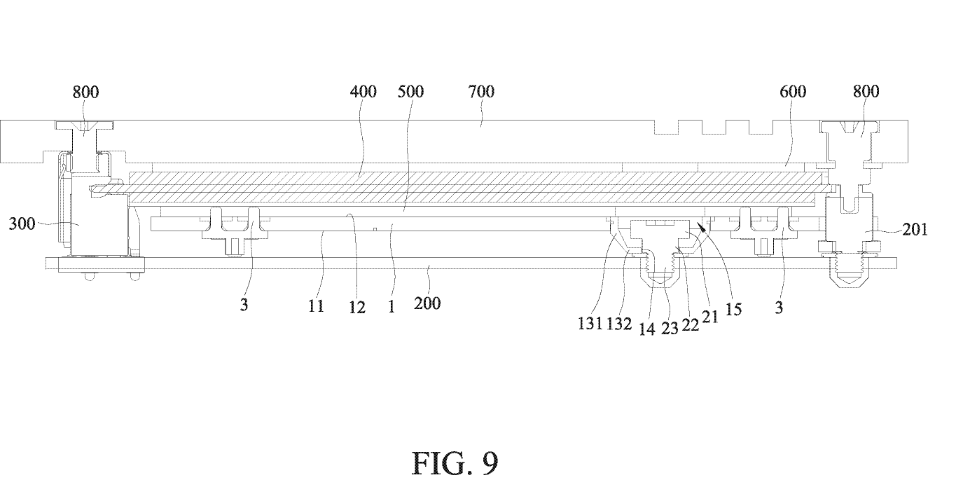

Since the elastic member 3 of the heat dissipation module 100 according to the present disclosure is elastic, and the thermally conductive member 1 is movable along the locking member 2, therefore, the heat dissipation module 100 can match with the storage component 400 of various thicknesses. For example, as shown in FIGS. 5, and 6, the storage component 400 has a smaller thickness H1, the angle θ1 between the wing portion 32 and the fixing portion 31 is smaller, and at this moment, the base plate 132 is close to the head portion 21 (i.e., the base plate 132 is away from the circuit board 200). By contrast, as shown in FIGS. 8, and 9, the storage component 400 has a large thickness H2, the angle θ2 between the wing portion 32 and the fixing portion 31 is larger (i.e., up to a maximum of 180 degrees, that is, the wing portion 32 is parallel to the fixing portion 31), and at this moment, the base plate 132 is away from the head portion 21 (i.e., the base plate 132 is close to the circuit board 200). Whether the protruding ring portion 13 is close to or away from the circuit board 200, the elastic force provided by the elastic member 3 can continuously cause the thermally conductive member 1 to be in contact with the storage component 400, thereby ensuring the thermal transfer efficiency.

In another embodiment, when the height of the connector 300 is lower or the thickness of the thermally conductive member 1 is thicker, and the protruding ring portion 13 moves along the locking member 2 and is close to the circuit board 200, the angle θ2 between the wing portion 32 and the fixing portion 31 increases, and the elastic member 3 is compressed (see the state of the elastic member 3 as shown in FIG. 8). When the height of the connector 300 is higher or the thickness of the thermally conductive member 1 is thinner, and the protruding ring portion 13 moves along the locking member 2 and is away from the circuit board 200, the angle θ1 between the wing portion 32 and the fixing portion 31 decreases, and the elastic member 3 is released (see the state of the elastic member 3 as shown in FIG. 5).

To sum up, the elastic member according to the present disclosure can effectively match to the thickness variations of each component within the heat dissipation module, or the thickness or height variations of each electronic component (e.g., connector) connected to the heat dissipation module, by undergoing compression or release. The elastic member automatically adjusts the interference amount applied to the storage component, thereby avoiding the storage component from being damaged due to over compressive strength, while simultaneously maintaining the heat transfer efficiency.

The above embodiments are provided for illustrating the principles and technical effects of the present disclosure, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A heat dissipation module for a circuit board having a connector connected to a storage component, the heat dissipation module comprising:
a thermally conductive member movably and floatingly disposed above the circuit board and including a first surface, a second surface opposing the first surface, a protruding ring portion, a through hole, and an accommodation space, wherein the first surface faces the circuit board, the protruding ring portion extends outward from the first surface of the thermally conductive member and surrounds and defines the accommodation space, such that the accommodation space is exposed at the second surface, and the through hole passes through the protruding ring portion and communicates with the accommodation space;
a locking member penetrating through the through hole, fixedly connected to the circuit board and including a head portion, wherein the head portion is accommodated in the accommodation space and is spaced apart from the circuit board; and
at least one elastic member connected to the first surface of the thermally conductive member, abutting against the circuit board, and configured to constantly provide an elastic force,
wherein the protruding ring portion of the thermally conductive member is configured to move close to or away from the circuit board along the locking member to compress or release the elastic member, and the elastic force is configured to maintain the thermally conductive member in contact with the storage component.

2. The heat dissipation module of claim 1, wherein the elastic member comprises a fixing portion and two wing portions, the fixing portion is fixedly connected to the first surface of the thermally conductive member, the two wing portions respectively extend outward from opposite sides of the fixing portion and abut against the circuit board, and the elastic member is configured to provide the elastic force by varying angles between the two wing portions and the fixing portion.

3. The heat dissipation module of claim 2, wherein the fixing portion includes two protruding posts, the thermally conductive member further includes at least two penetrating holes, and the two protruding posts respectively penetrate through the two penetrating holes.

4. The heat dissipation module of claim 3, wherein each of the two protruding posts is configured to be heat-melted to include a head section and a stem section, the head section and the stem section jointly form a T-shaped cross section, the stem sections of the two protruding posts penetrate through the two penetrating holes, and the head sections of the two protruding posts abut against the second surface of the thermally conductive member.

5. The heat dissipation module of claim 2, wherein each of the two wing portions includes a support post, and the support posts abut against the circuit board and respectively correspond to opposite long edges of the thermally conductive member.

6. The heat dissipation module of claim 1, wherein the locking member includes a stepped portion and a threaded portion, the stepped portion extends outward from the head portion and penetrates through the through hole, and the threaded portion extends outward from the stepped portion and is fixedly threaded to the circuit board.

7. The heat dissipation module of claim 6, wherein a cross-sectional area of the head portion is larger than a cross-sectional area of the through hole, and the cross-sectional area of the through hole is larger than a cross-sectional area of the stepped portion.

8. The heat dissipation module of claim 6, wherein the protruding ring portion includes a ring wall and a base plate connected to an end of the ring wall, the through hole passes through the base plate, a thickness of the base plate is less than a height of the stepped portion, and the base plate is configured to move along the stepped portion and is limited between the head portion and the circuit board.

9. The heat dissipation module of claim 1, further comprising a first thermally conductive adhesive pad disposed on the second surface, and being in contact with the storage component disposed over the second surface of the thermally conductive member.

10. The heat dissipation module of claim 1, further comprising a heat dissipation sheet disposed on the storage component, and a second thermally conductive adhesive pad disposed between the heat dissipation sheet and the storage component.

11. The heat dissipation module of claim 10, wherein the circuit board includes a fixed screw, the fixed screw and the connector are respectively correspondingly adjacent to opposite short edges of the thermally conductive member, a plurality of fastening members penetrate through the heat dissipation sheet and are respectively fixedly screw-fastened to the connector and the fixed screw, and the heat dissipation sheet is in contact with the second thermally conductive adhesive pad.
